(19) United States
(12) Patent Application Publication
(10) Pub. No.: US 2026/0164872 A1
(43) Pub. Date: Jun. 11, 2026

(54) APPARATUS FOR MANUFACTURING DISPLAY DEVICE, BENDING APPARATUS, AND METHOD FOR MANUFACTURING DISPLAY DEVICE

(71) Applicant: Samsung Display Co., Ltd., Yongin-si (KR)

(72) Inventors: HYUNGJUN YU, Yongin-si (KR); Myung Gil CHOI, Yongin-si (KR); Dong Woo KIM, Yongin-si (KR); SANGHOON PARK, Yongin-si (KR); WONJUN CHOI, Yongin-si (KR)

(21) Appl. No.: 19/180,043

(22) Filed: Apr. 15, 2025

(30) Foreign Application Priority Data
Jun. 25, 2024 (KR) 10-2024-0083172
Sep. 24, 2024 (KR) 10-2024-0129167

(51) Int. Cl. H10H 29/01; H10P 72/00

(52) U.S. Cl. CPC H10H 29/012; H10P 72/0428

(57) ABSTRACT

A manufacturing apparatus of a display device includes: a multi-axis robot, and a bending apparatus. The bending apparatus includes: a connector configured to be removably mounted to the multi-axis robot; and a main body supported by the connector and configured to bend a target substrate. The main body includes: a central frame extending in a first direction; an extension frame integrally combined with the central frame and extending from the central frame in a second direction crossing the first direction; an adsorption part on the extension frame; and a rotation member connected to an end of the central frame and configured to rotate the adsorption part about a first rotation axis that is parallel to the first direction.

### CROSS-REFERENCE TO RELATED APPLICATION

The present application claims priority to and the benefit of Korean Patent Application Nos. 10-2024-0083172 and 10-2024-0129167, filed on Jun. 25, 2024 and Sep. 24, 2024, respectively, in the Korean Intellectual Property Office, the entire disclosures of which are incorporated herein by reference.

### BACKGROUND

### 1. Field

Aspects of embodiments of the present disclosure relate to an apparatus for manufacturing a display device, a bending apparatus, and a manufacturing method of a display device.

### 2. Description of the Related Art

A display device may include a display panel configured to display an image and a flexible printed circuit board (FPCB) that is connected to the display panel and transmits signals to the display panel.

A manufacturing method of the display device may include a process of folding a flexible printed circuit board by using a manufacturing apparatus or a bending apparatus.

### SUMMARY

Embodiments of the present disclosure are directed to an apparatus for manufacturing a display device, a bending apparatus, and a manufacturing method for a display device that may freely bend a flexible printed circuit board without restrictions as to a size or a shape of the display panel or a position at where the flexible printed circuit board is joined to the display panel.

A manufacturing apparatus of a display device, according to an embodiment of the present disclosure, includes a multi-axis robot and a bending apparatus including a connector configured to be removably mounted to the multi-axis robot and a main body supported by the connector and configured to bend a target substrate. The main body includes a central frame extending in a first direction, an extension frame integrally combined with the central frame and extending from the central frame in a second direction crossing the first direction, an adsorption part on the extension frame, and a rotation member connected to an end of the central frame and configured to rotate the adsorption part about a first rotation axis that is parallel to the first direction.

The extension frame may include a first extension frame and a second extension frame extending in opposite directions from the central frame along the second direction, and the adsorption part may include a first adsorption part on the first extension frame and a second adsorption part on the second extension frame.

The adsorption part may include an adsorption surface configured to receive the target substrate and a pressurizing part between the adsorption surface and the extension frame and configured to move the adsorption surface.

The rotation member may include a rotation coupling part connected to an end of the central frame and configured to rotate around the first rotation axis, a rotation reducer connected to the rotation coupling part in the first direction, and a rotation driving part connected to the rotation reducer and configured to provide a driving torque that rotates the rotation coupling part.

The rotation member may include a sensor part between the rotation coupling part and the rotation reducer configured to detect a rotation angle of the central frame.

The central frame may have a first end to which the rotation member is coupled and a second end opposite to the first end in the first direction, and the main body may include a body frame between the connector and the rotation member, a first reinforcement frame extending from the second end along a third direction crossing the first direction and the second direction, respectively, and a second reinforcement frame separated from the central frame and connecting the first reinforcement frame and the body frame.

A minimum separation distance between the central frame and the second reinforcement frame may be greater than the length of the extension frame in the second direction.

The main body may include a body frame between the connector and the rotation member, and a grip part extending along the second direction from the body frame and having a shutoff-capable forceps shape at an end of the second direction.

The main body may include a pressurization frame extending from the central frame along a third direction crossing each of the first direction and the second direction and configured to rotate about a second rotation axis parallel to the first direction and a protruding part that protrudes in the second direction from a surface of the pressurization frame extending along the first direction.

A bending apparatus, according to an embodiment of the present disclosure, includes a connector configured to be removably attachable to a multi-axis robot and a main body configured to be suspended and supported by the connector and configured to bend the target substrate. The main body includes a central frame extending in a first direction, an extension frame integrally combined with the central frame and extending from the central frame in a second direction crossing the first direction, an adsorption part on the extension frame, and a rotation member connected to an end of the central frame and configured to rotate the adsorption part about a first rotation axis that is parallel to the first direction.

The extension frame may include a first extension frame and a second extension frame extending in opposite directions from the central frame along the second direction, and the adsorption part may include a first adsorption part on the first extension frame and a second adsorption part on the second extension frame.

The adsorption part may include an adsorption surface configured to receive the target substrate and a pressurizing part between the adsorption surface and the extension frame and configured to move the adsorption surface.

The rotation member may include a rotation coupling part connected to an end of the central frame and configured to rotate around the first rotation axis, a rotation reducer connected to the rotation coupling part in the first direction, and a rotation driving part connected to the rotation reducer and configured to provide a driving torque to rotate the rotation coupling part.

The central frame may have a first end to which the rotation member is coupled and a second end opposite to the first end in the first direction, and the main body may include a body frame between the connector and the rotation member, a first reinforcement frame extending from the second end along a third direction crossing the first direction and the second direction, respectively, and a second reinforcement frame separated from the central frame and connecting the first reinforcement frame and the body frame.

The main body may include a body frame between the connector and the rotation member and a grip part extending along the second direction from the body frame and having a shutoff-capable forceps shape at an end of the second direction.

The main body may include a pressurization frame extending from the central frame along a third direction crossing each of the first direction and the second direction and configured to rotate about a second rotation axis parallel to the first direction and a protruding part that protrudes in the second direction from a surface of the pressurization frame extending along the first direction.

A manufacturing method of a display device, according to an embodiment of the present disclosure, includes preparing a bending apparatus including a connector configured to be removably attachable to a multi-axis robot and a main body including an adsorption part and suspended from the connector, moving the multi-axis robot to position the adsorption part under a target substrate, adsorbing a part of the target substrate by the adsorption part, bending the target substrate by moving the multi-axis robot and concurrently rotating the adsorption part, and moving the multi-axis robot to move the adsorption part away from the target substrate.

The adsorption part may include an adsorption surface and a pressurizing part connected to the adsorption surface.

The method may further include pressurizing the adsorption surface by using the pressurizing part.

The main body may include a grip part having a shutoff-capable forceps shape at an end, and the method may further include peeling off the release paper by using the grip part.

The main body may include a central frame extending in a first direction, an extension frame integrally combined with the central frame and extending from the central frame in a second direction crossing the first direction, a pressurization frame configured to extend from the central frame along a third direction crossing each of the first direction and the second direction and to rotate about a second rotation axis parallel to the first direction; and a protruding part protruding in the second direction on a surface of the pressurization frame extending along the first direction, and the method may further include pressurizing the protruding part of the bent target substrate by rotating the pressurization frame.

According to embodiments of the present disclosure, the flexible circuit board may be freely bent without restrictions as to the size or shape of the display panel or the position at which the flexible printed circuit board is bonded to the display panel.

Additionally, other aspects and features of the present disclosure will be learned throughout the specification.

### BRIEF DESCRIPTION OF THE DRAWINGS

FIG. 1 is a perspective view schematically illustrating a display device.

FIG. 2 is a cross-sectional view schematically illustrating a display panel before a bending process.

FIG. 3 is a cross-sectional view schematically illustrating a display panel after a bending process.

FIG. 4 is a perspective view illustrating an apparatus for manufacturing a display device according to an embodiment.

FIG. 5 is a perspective view illustrating an apparatus for manufacturing a display device according to another embodiment.

FIG. 6 is a perspective view illustrating a bending apparatus according to an embodiment.

FIG. 7 is a perspective view showing the bending apparatus shown in FIG. 6 in an inverted position.

FIG. 8 illustrates a connector included in a bending apparatus according to an embodiment.

FIG. 9 is an illustration of a pressurizing part included in a bending apparatus according to an embodiment.

FIG. 10 is an illustration of a sensor part included in a bending apparatus according to an embodiment.

FIG. 11 to FIG. 14 are views illustrating a manufacturing method of a display device according to an embodiment.

FIG. 15 to FIG. 17 are views illustrating a pressurization process of a bending apparatus according to an embodiment.

FIG. 18 is a view illustrating a bending apparatus according to an embodiment for sequentially bending different flexible printed circuit boards.

FIG. 19 is a flowchart describing a manufacturing method of a display device according to an embodiment.

FIG. 20 is a flowchart describing a manufacturing method of a display device according to an embodiment.

### DETAILED DESCRIPTION

The present disclosure will be described more fully hereinafter with reference to the accompanying drawings, in which embodiments of the present disclosure are shown. As those skilled in the art would realize, the described embodiments may be modified in various different ways, all without departing from the spirit or scope of the present disclosure.

Descriptions of aspects, features, parts, and configurations not related to the present disclosure may be omitted or only briefly described.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

Further, in the specification, the phrase “on a plane” means viewing the target part from the top (or from above), and the phrase “on a cross-section” means viewing a cross-section of which the target part is vertically cut from the side.

A display device is an electronic device configured to visually display various forms of information. A display device may be used to display text, images, videos, etc. Display devices include a liquid crystal display (LCD), a light emitting diode display, an organic light emitting diode (OLED) display, a quantum dot display, etc.

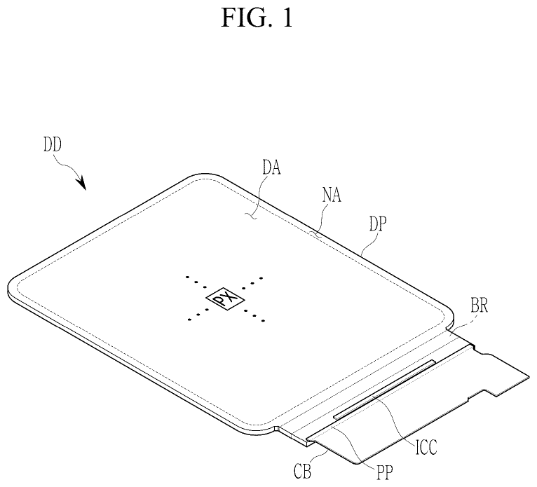

FIG. 1 is a perspective view schematically illustrating a display device.

A display device DD is described with reference to FIG. 1. The display device DD may include a display panel DP, a flexible printed circuit board CB connected to the display panel DP, and a driving apparatus including an integrated circuit (IC) chip ICC.

The display panel DP may have a display area DA and a non-display area NA. The display area DA may correspond to a screen on which an image is displayed. The non-display area NA may be an area where circuits and signal lines are arranged to generate or transmit various signals applied to the display area DA. The non-display area NA may surround (e.g., may extend around a periphery of) the display area DA.

In the display area DA of the display panel DP, pixels PX may be arranged in a matrix arrangement. Additionally, signal lines, such as a gate line (also called a scan line), a data line, and a driving voltage line may be arranged in the display area DA. Each pixel PX may be connected to the gate line, the data line, the driving voltage line, etc., and may receive a gate signal (also called a scan signal), a data voltage, and a driving voltage (also called a first power voltage or a high-potential power voltage) from these signal lines. The pixel PX may be the smallest unit that may display a contrast (e.g., the smallest unit that may emit light). One pixel PX may correspond to one light emitting area, and a planar shape of the pixel PX may be defined by the corresponding light emitting area. Each pixel PX may display one of the primary colors, such as red, green, and blue. The pixel PX may be implemented by a light emitting element, such as an organic or inorganic light emitting diode, and a pixel circuit connected to the light emitting element.

The display area DA may include a touch sensor layer for sensing a contact or non-contact (e.g., a near-contact) touch of a user. Although the display area DA, in the illustrated embodiment, has a quadrangular shape, the display area DA may have various shapes, such as a polygonal shape, a circular shape, an elliptical shape, etc.

A pad part PP at where pads for receiving the signals from outside of the display panel DP is disposed in the non-display area NA of the display panel DP. The pad part PP may be disposed along one edge of the display panel DP. A flexible printed circuit board CB may be bonded to the pad part PP, and pads of the flexible printed circuit board CB may be electrically connected to pads of the pad part PP.

A driving apparatus (e.g., a driving unit) that generates or processes various signals for driving the display panel DP may be disposed in the non-display area NA of the display panel DP. The driving apparatus may include a data driver that applies a data voltage to the data lines, a gate driver that applies a gate signal to the gate lines, and a signal controller that controls the data driver and the gate driver. The pixels PX may receive the data voltage at a specific timing according to the gate signal generated by the gate driver. The gate driver may be integrated into the display panel DP and disposed on at least one side of the display area DA. The data driver and the signal controller may be provided as an IC chip (also called a driving IC chip) ICC, and the IC chip ICC may be mounted in the non-display area NA of the display panel DP. The IC chip ICC may be mounted on the flexible printed circuit board CB, etc. and electrically connected to the display panel DP.

The display panel DP may have at least one or more bending regions BR. The bending region BR may be disposed in the non-display area NA between the display area DA and the pad part PP. The display panel DP may be bent to have a curvature radius (e.g., a predetermined curvature radius) with reference to a bending axis parallel to a direction in which the bending region BR extends. The display panel DP may be bent so that the pad part PP and the flexible printed circuit board CB, which are located farther from the display area DA than the bending region BR is, are disposed on (or are arranged on or over) the back surface of the display panel DP. In the display device DD at the conclusion of the manufacturing process, the display panel DP may be bent as described above. The bending region BR may be disposed throughout (e.g., may extend throughout) the display area DA and the non-display area NA or may be disposed in the display area DA.

Additionally, the display panel DP may not have the bending region BR, and the flexible printed circuit board CB may have the bending region BR. In such an embodiment, the flexible printed circuit board CB may be bent to wrap (or extend) around the edge at where the pad part PP of the display panel DP is disposed so that most of the flexible printed circuit board CB may be disposed on the back surface of the display panel DP.

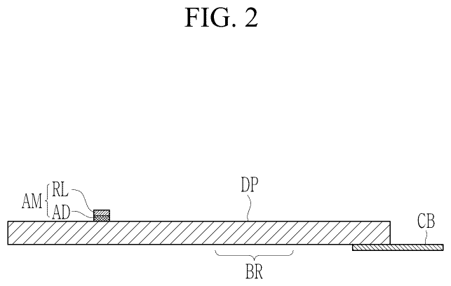

FIG. 2 is a cross-sectional view schematically illustrating a display panel before a bending process.

FIG. 2 shows a display panel DP, a flexible printed circuit board CB, and an adhesive member AM before being bent. The adhesive member AM may include an adhesive AD and a release paper RL.

The flexible printed circuit board CB may be bonded to an end of the display panel DP. The adhesive member AM may be disposed on a part of the back surface of the display panel DP. The release paper RL may protect the adhesive AD. Additionally, the release paper RL may be easily peeled off. The release paper RL may be peeled off before bending the display panel DP or the flexible printed circuit board CB. For example, the release paper RL may be peeled by a release paper peeling device having a forceps shape. The adhesive AD may affix the bent display panel DP or flexible printed circuit board CB. The position of the adhesive member AM may vary depending on the position of the bending region BR.

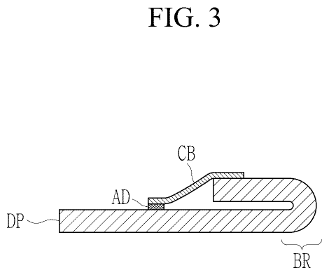

FIG. 3 is a cross-sectional view schematically illustrating the display panel shown in FIG. 2 after the bending process.

FIG. 3 shows the display panel DP, the flexible printed circuit board CB, and the adhesive AD, are the bending process. The bending region BR may be in the display panel DP.

The display panel DP may be bent to bond the flexible printed circuit board CB to the back surface of the display panel DP. The display panel DP may be bent in the bending region BR. The adhesive AD is disposed on the back surface of the display panel DP, and the display panel DP and the flexible printed circuit board CB may be bonded by the adhesive AD. The flexible printed circuit board CB may be bent flexibly. The back surface of the display panel DP may be a surface of the display panel DP on which no image is displayed. By performing the bending process, the area of the non-display area NA of the display panel DP may be reduced. Additionally, by performing the bending process, the display device DD may be miniaturized while maintaining the size of the display area DA.

FIG. 3 shows a display panel DP on which a bending process was performed, where the release paper RL shown in FIG. 2 was peeled off before the bending process was performed. By peeling off the release paper RL, the adhesive AD may bond the display panel DP and the flexible printed circuit board CB to each other. After the bending process is performed, a process may be performed so that the flexible printed circuit board CB and the display panel DP may be strongly bonded. For example, a process may be performed to physically pressurize a part of the flexible printed circuit board CB that overlaps the adhesive AD.

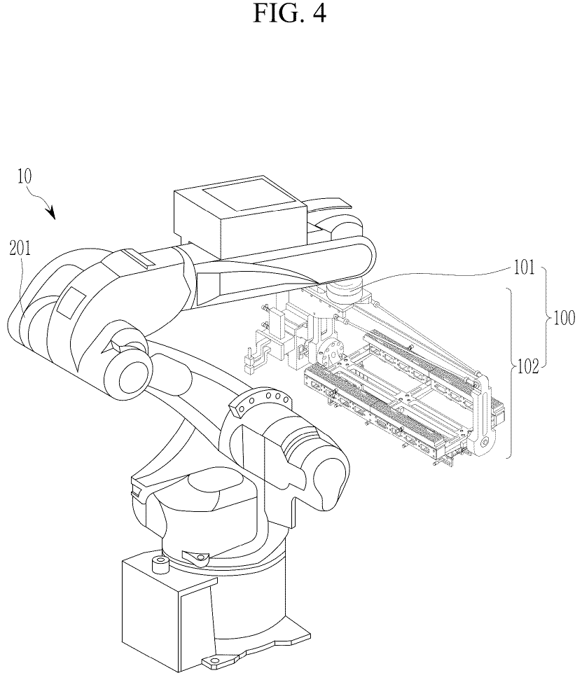

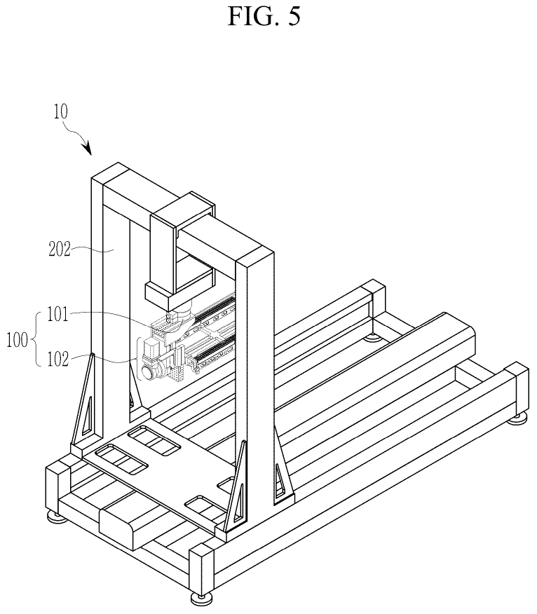

FIG. 3 illustrates an embodiment in which the bending region BR of the display panel DP is bent. In another embodiment, the bending area of the flexible printed circuit board CB bonded to the pad part PP of the display panel DP may be bent. The bending area of the display panel DP or the flexible printed circuit board CB may be bent by a bending apparatus or an apparatus for manufacturing the display device including a bending apparatus. FIG. 4 and FIG. 5 illustrate a manufacturing apparatus for a display device including a bending apparatus and a multi-axis robot.

FIG. 4 is a perspective view illustrating an apparatus for manufacturing a display device according to an embodiment.

The manufacturing apparatus 10 of the display device shown in FIG. 4 may include a multi-axis robot and a bending apparatus 100. The multi-axis robot shown in FIG. 4 may be a multi-joint robot 201. The multi-joint robot 201 is a robot with multiple rotation joints that may move like a human arm.

The bending apparatus 100 includes a connector 101, and the bending apparatus 100 may be connected to the multi-joint robot 201 through the connector 101. The bending apparatus 100 may be suspended from (e.g., coupled to) the multi-joint robot 201 via the connector 101. Therefore, the bending apparatus 100 may be moved while being suspended from the multi-joint robot 201. The bending apparatus 100 may move freely in space (e.g., in a space around the multi-joint robot 201) in a first direction D1, a second direction D2, or a third direction D3. The bending apparatus 100 may approach a target substrate according to the motion of the multi-joint robot 201. The bending apparatus 100 may bend the target substrate according to the motion of the multi-joint robot 201. The bending apparatus 100 may not remain fixed in position during the bending process. The bending apparatus 100 may bend the target substrate regardless of the position of the flexible printed circuit board CB on the display panel DP.

FIG. 5 is a perspective view illustrating a manufacturing apparatus of a display device according to another embodiment.

The manufacturing apparatus 10 of the display device shown in FIG. 5 may include a multi-axis robot and a bending apparatus 100. The multi-axis robot shown in FIG. 5 may be a multi-axis orthogonal robot 202. The multi-axis orthogonal robot 202 may move along (or may consist of) three or more linear axes. The multi-axis orthogonal robot 202 may provide high precision and stability because it has a structure in which each axis is orthogonal to the others.

The manufacturing apparatus 10 of the display device shown in FIG. 4 illustrates the multi-joint robot 201 as a multi-axis robot, and the manufacturing apparatus 10 of the display device shown in FIG. 5 illustrates the multi-axis orthogonal robot 202 as a multi-axis robot. Also, in another embodiment, the multi-axis robot may be a cylindrical robot, a polar robot, a SCARA robot, a humanoid robot. In other words, the types of the multi-axis robots is not limited.

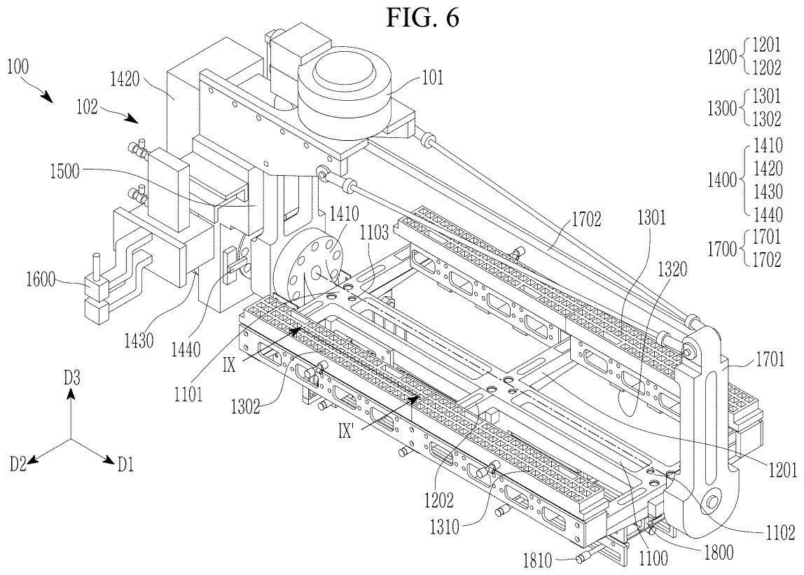

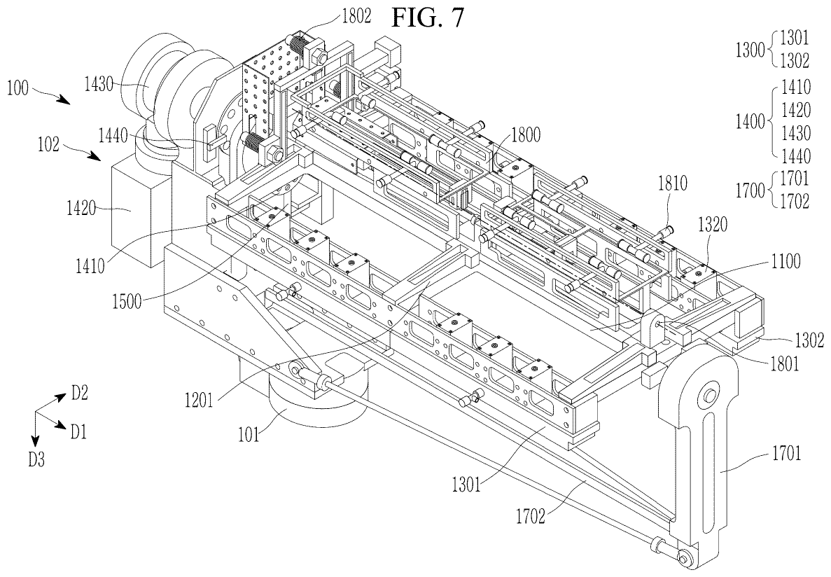

The bending apparatus mounted on the multi-axis robot shown in FIG. 4 and FIG. 5 is described in more detail with reference to FIG. 6 and FIG. 7.

FIG. 6 is a perspective view illustrating a bending apparatus according to an embodiment. FIG. 7 is a perspective view showing the bending apparatus shown in FIG. 6 in an inverted orientation.

The bending apparatus 100 shown in FIG. 6 may bend the display panel DP or the flexible printed circuit board CB. FIG. 7 is a perspective view of the bending device of FIG. 6 viewed by rotating it 180 degrees around the rotation axis extending in the first direction D1. That is, FIG. 6 is a perspective view of the bending apparatus 100 seen from above, and FIG. 7 is a perspective view of the bending apparatus 100 seen from below.

Hereinafter, the bending apparatus 100 according to an embodiment is described with reference to FIG. 6 and FIG. 7.

The bending apparatus 100 may include the connector 101 and a main body 102. The connector 101 may be configured to be attachable to or detachable from the multi-axis robot. The main body 102 may be connected to the connector 101. The main body 102 is supported by being suspended from (e.g., coupled to) the connector 101 and may be configured to bend the target substrate. The target substrate is a substrate to be bent and may be the display panel DP or the flexible printed circuit board CB to be bent by the bending apparatus 100.

The main body 102 may include a central frame 1100, an extension frame 1200 integrally combined (or integrally formed) therewith, an adsorption part 1300 for adsorbing (e.g., attaching via suction or vacuum) the target substrate, and a rotation member 1400 for rotating the adsorption part 1300. In addition, the main body 102 may include a body frame 1500 that connects the rotation member 1400 to the connector 101, a grip part 1600 extending therefrom, a reinforcement frame 1700 for reinforcing the rigidity of the central frame 1100 and the extension frame 1200, a pressurization frame 1800 that pressurizes the target substrate to be bent, and a protruding part 1810 that protrudes for this purpose. Each component of the main body 102 is described below.

The central frame 1100 may extend along the first direction D1. The central frame 1100 may rotate around a first rotation axis 1103, which is parallel to the first direction D1. The central frame 1100 is not flexible, that is, it does not change shape.

The length of the central frame 1100 in the first direction D1 may vary depending on the width and length of the target substrate. The bending apparatus 100 may be prepared with different lengths of the central frame 1100 in the first direction D1. The size of the bending apparatus 100 may be determined according to the length of the central frame 1100 in the first direction D1.

The extension frame 1200 may be integrally combined with the central frame 1100. The extension frame 1200 may extend from the central frame 1100 in the second direction D2 crossing (or intersecting) the first direction D1. The second direction D2 may be orthogonal to the first direction D1. There may be one or more extension frames 1200. The extension frame 1200 may include a first extension frame 1201 and a second extension frame 1202 extending in opposite directions from the central frame 1100 along the second direction D2. The extension frame 1200 may extend along the second direction D2 from the end of the central frame 1100. Additionally, the extension frame 1200 may extend along the second direction D2 from the center of the central frame 1100. The extension frame 1200 is not flexible, that is, it does not change shape.

The adsorption part 1300 may adsorb the target substrate. The adsorption part 1300 may be disposed on the extension frame 1200. For example, the adsorption part 1300 may be disposed at the end of extension frame 1200 in the second direction D2. The adsorption part 1300 may extend along the first direction D1. The adsorption part 1300 may be disposed over the plurality of extension frames 1200. There may be one or more adsorption parts 1300. The plurality of adsorption parts 1300 may be disposed facing the central frame 1100 as a reference. The adsorption part 1300 may rotate in both clockwise and counterclockwise directions about the first rotation axis 1103. In an embodiment in which the main body 102 includes the plurality of adsorption parts 1300 facing the central frame 1100 as a reference, the adsorption part 1300 is selected to enable bending of the target substrate. For example, the adsorption part 1300 placed under the target substrate may be selected depending on the rotational motion direction of the adsorption part 1300. The adsorption part 1300 may include a first adsorption part 1301 disposed on the first extension frame 1201 and a second adsorption part 1302 disposed on the second extension frame 1202. In one embodiment, there may be one first adsorption part 1301 and one or more second adsorption parts 1302.

The target substrate adsorbed by the adsorption part 1300 may be bent by the movement of the bending apparatus 100 and the rotation of the adsorption part 1300. The adsorption part 1300 may rotate around the first rotation axis 1103, which is parallel to the first direction D1. The adsorption part 1300 may be moved according to the motion of the multi-axis robot.

There are no restrictions on the way in which the adsorption part 1300 adsorbs the target substrate. For example, the adsorption part 1300 may adsorb by using vacuum suction, electrostatic chuck, mechanical clamping, and adhesive bonding.

The adsorption part 1300 may include a pressurizing part 1320 configured to pressurize the target substrate. This will be described in more detail later.

The rotation member 1400 may include a rotation coupling part 1410, a rotation driving part 1420, a rotation reducer 1430, and a sensor part 1440. The rotation member 1400 may be attached to an end of the central frame 1100. The rotation member 1400 may be configured to rotate the adsorption part 1300 around the first rotation axis 1103 parallel to the first direction D1. The rotation member 1400 may be disposed at a first end 1101 of the central frame 1100. The central frame 1100 may have a second end 1102 facing the first end 1101 in the first direction.

The rotation coupling part 1410 may be disposed at the first end 1101 of the central frame 1100. The rotation coupling part 1410 may be connected to the central frame 1100. For example, the rotation coupling part 1410 may be in contact with the central frame 1100. The rotation coupling part 1410 may be disposed between the rotation reducer 1430 and the central frame 1100. The rotation member 1400 may rotate in both clockwise and counterclockwise directions about the first rotation axis 1103. The first rotation axis 1103 may be the center of the rotation member 1400. The first rotation axis 1103 may be the center of the rotational motion of the rotation coupling part 1410. The central frame 1100 may perform the rotational movement together with the rotational movement of the rotation coupling part 1410.

The rotation reducer 1430 may be disposed away from the rotation coupling part 1410 in the first direction D1. The rotation reducer 1430 may be connected to the rotation coupling part 1410 along the first direction D1. The rotation reducer 1430 may transfer rotational kinetic energy to the rotation coupling part 1410. The rotation reducer 1430 may receive the rotational kinetic energy from the rotation driving part 1420. For example, the rotation reducer 1430 may receive the rotational kinetic energy from the rotation driving part 1420 through gears. The rotation reducer 1430 may reduce the speed of the rotation movement. Additionally, the rotation reducer 1430 may increase the torque of the rotation movement. The rotation reducer 1430 may convert the rotation driving part 1420 to an appropriate speed when it rotates at a high speed. For example, the rotation reducer 1430 may convert the speed and the torque through a gear ratio of the gears.

The rotation driving part 1420 may be connected to the rotation reducer 1430. The rotation driving part 1420 may provide the driving torque to rotate the rotation coupling part 1410. The rotation driving part 1420 may convert the electrical energy into the rotational kinetic energy. For example, the rotation driving part 1420 may be a motor. The electrical energy for the rotation driving part 1420 may be applied from the multi-axis robot through the connector 101. In another embodiment, the electrical energy for the rotation driving part 1420 may be supplied from the battery of the bending apparatus 100. The rotation driving part 1420 may include gears.

The rotation coupling part 1410 may transfer the rotational kinetic energy from the rotation reducer 1430 to the central frame 1100. The central frame 1100 may be integrally formed with the extension frame 1200, and the adsorption part 1300 may be disposed on the extension frame 1200. Therefore, when the central frame 1100 rotates, the adsorption part 1300 also rotates. The adsorption part 1300 may rotate in a clockwise or counterclockwise direction about the first rotation axis 1103. The target substrate may be bent by rotating the adsorption part 1300. The rotation reducer 1430 may control the rotation speed and the torque of the adsorption part 1300 to enable the adsorption part 1300 to move precisely.

The body frame 1500 may be disposed between the connector 101 and the rotation member 1400. The body frame 1500 may support the main body 102. For example, the body frame 1500 may support the connector 101, the rotation member 1400, and the central frame 1100. The size and shape of the body frame 1500 are not limited. The body frame 1500 is not flexible, that is, its shape does not change.

The Interior of the body frame 1500 may include power lines or signal lines connected via the connector 101 and supplied from the multi-axis robot. The power line may be connected to the rotation driving part 1420 and may supply the electrical energy to the rotation driving part 1420. Additionally, the power line may supply the electrical energy to the rotation reducer 1430 and the sensor part 1440. The signal line may transmit the control signal of the multi-axis robot to each component of the bending apparatus 100. For example, the rotation driving part 1420 may receive the driving signal from the multi-axis robot through the signal lines. Additionally, the sensor part 1440 may receive the sensing instruction signals from the multi-axis robot through the signal lines.

The grip part 1600 may perform a peeling process to peel off the release paper RL of the adhesive member AM before performing the bending process. The grip part 1600 may be formed by extending from the body frame 1500 along the second direction D2. The grip part 1600 may have a shutoff-capable gripper shape at the end. The gripper shape of the grip part 1600 is a shape that may grip the release paper RL and is not limited to a specific shape. The grip part 1600 may extend in the second direction D2 sufficiently to peel off the release paper RL.

The bending apparatus 100 may move according to the motion of the multi-axis robot. The bending apparatus 100 may move the release paper RL and the grip part 1600 closer together. Additionally, the bending apparatus 100 may move in a direction in which the grip part 1600 picks up the release paper RL and then peels off the release paper RL. Because the bending apparatus 100 includes the grip part 1600, the peeling process and the bending process may be performed quickly and simply. A separate peeling device is generally required for the peeling process conventionally, by including the grip part 1600 in the bending apparatus, the need for a separate peeling device may be removed.

The reinforcement frame 1700 may support the bending apparatus 100 to ensure stability. For example, the reinforcement frame 1700 may stably support the central frame 1100, the extension frame 1200, and the adsorption part 1300. The reinforcement frame 1700 may include a first reinforcement frame 1701 and a second reinforcement frame 1702. The first reinforcement frame 1701 may extend from the second end 1102 of the central frame 1100 along the third direction D3 crossing (e.g., intersecting) the first direction D1 and the second direction D2, respectively. The second end 1102 of the central frame 1100 may be the end at where the rotation member 1400 is not coupled from among the ends of the central frame 1100. Additionally, the second end 1102 of the central frame 1100 may be the end that is furthest from the rotation member 1400 from among the ends of the central frame 1100. The second reinforcement frame 1702 may be disposed apart from the central frame 1100. The second reinforcement frame 1702 may connect the first reinforcement frame 1701 and the body frame 1500. The second reinforcement frame 1702 may have a shape extending in the first direction D1. The reinforcement frame 1700 is not flexible, that is, its shape does not change.

The main body 102 of the bending apparatus 100 may be supported by only the connector 101 to be suspended in the air. In the bending apparatus 100 according to an embodiment, the connector 101 may be disposed at the first end 1101 from among both ends of the central frame 1100. Accordingly, the central frame 1100, the extension frame 1200, and the adsorption part 1300, which extend in the first direction D1, may bend the direction of gravity due to their own weight and/or load. In other words, the second end 1102 of the two ends of the central frame 1100 that is farther away from the connector 101 may bend in the direction of gravity. Therefore, the main body 102 may be stabilized by connecting the reinforcement frame 1700, which extends from the second end 1102 of the central frame 1100, to the body frame 1500. Because the second end 1102 together with the first end 1101 of the central frame 1100 is directly supported by the body frame 1500, the bending apparatus 100 may be stably supported and may not bend.

The adsorption part 1300 of the bending apparatus 100 may bend the target substrate by performing the rotational movement around the first rotation axis 1103 while adsorbing at least a part of the target substrate. The adsorption part 1300 may be disposed on the extension frame 1200 extending along the second direction D2 from the central frame 1100. For example, the adsorption part 1300 may be disposed at the end of the extension frame 1200 in the second direction D2. Accordingly, the radius of the rotation of the adsorption part 1300 around the first rotation axis 1103 may be equal to the length of the extension frame 1200 in the second direction D2. The central frame 1100 and the second reinforcement frame 1702 are separated, but if the separation distance between the central frame 1100 and the second reinforcement frame 1702 is not sufficient, the second reinforcement frame 1702 may interfere with the rotational movement of the adsorption part 1300. The separation distance between the central frame 1100 and the second reinforcement frame 1702 may be a distance between the central frame 1100 and the second extension frame 1202. The minimum separation distance between the central frame 1100 and the second reinforcement frame 1702 may be a distance between the closest parts of the central frame 1100 and the second extension frame 1202. Considering the rotational movement of the adsorption part 1300, the minimum separation distance between the central frame 1100 and the second reinforcement frame 1702 is preferably greater than the length of the extension frame 1200 in the second direction D2.

The pressurization frame 1800 may be disposed to extend from the central frame 1100 along the third direction D3, which crosses (or intersects) each of the first direction D1 and the second direction D2. The pressurization frame 1800 may be configured to rotate about a second rotation axis 1801 that is parallel to the first direction D1. The second rotation axis 1801 may be the central axis around which the pressurization frame 1800 rotates. The second rotation axis 1801 may be disposed in the third direction D3 away from the first rotation axis 1103. The second rotation axis 1801 may be disposed between the protruding part 1810 and the central frame 1100. The second rotation axis 1801 may be disposed away from the central frame 1100 in the third direction D3. The pressurization frame 1800 may extend along the first direction D1. A surface of the pressurization frame 1800 extending in the first direction D1 may include a protruding part 1810 protruding in the second direction D2. The protruding part 1810 may be disposed away from the central frame 1100 in the third direction D3. The protruding part 1810 may be disposed away from the second rotation axis 1801 in the third direction D3. The protruding part 1810 may be integrally connected to the pressurization frame 1800. After the bending process, the pressurization frame 1800 may rotate around the second rotation axis 1801 to pressurize the target substrate adsorbed by the adsorption part 1300 by the protruding part 1810. In this way, the target substrate may be strongly adhered to the display panel DP.

The length of the pressurization frame 1800 in the first direction D1 may be approximately equal to the length of the adsorption part 1300 in the first direction D1. Additionally, the length of the pressurization frame 1800 in the first direction D1 may be the same as the length of the central frame 1100 in the first direction D1. Therefore, the plurality of protruding parts 1810 may sufficiently pressurize the adsorption region of the target substrate being adsorbed by the adsorption part 1300 along the first direction D1.

There may be one or more protruding parts 1810. The parts of the plurality of protruding parts 1810 may be arranged and disposed at an interval (e.g., a predetermined interval) along the first direction D1. Some of the plurality of protruding parts 1810 may extend in opposite directions from the pressurization frame 1800 along the second direction D2. By including the plurality of protruding parts 1810 extending in opposite directions along the second direction D2 centered on the pressurization frame 1800, the target substrate may be pressurized using the protruding parts 1810 regardless of the rotating direction (clockwise or counterclockwise direction) of the bending apparatus 100.

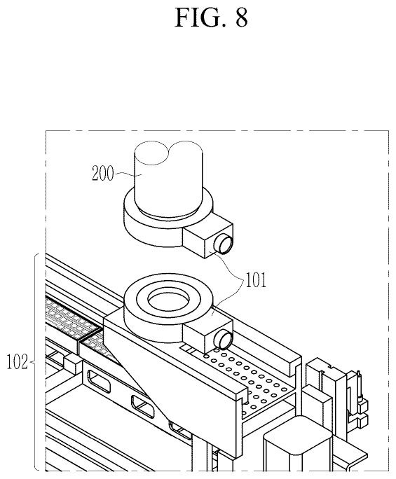

FIG. 8 is a view of a connector included in a bending apparatus according to an embodiment.

The multi-axis robot 200 shown in FIG. 8 may be the multi-joint robot 201 illustrated in FIG. 4 or the multi-axis orthogonal robot 202 illustrated in FIG. 5.

The connector 101 may connect the multi-axis robot 200 and the bending apparatus 100. The connector 101 may connect the power line and signal line of the multi-axis robot 200 and the bending apparatus 100. The multi-axis robot 200 and the bending apparatus 100 may be connected through an interface and may exchange signals with each other.

The size of the bending apparatus 100 may vary, as needed. For example, the bending apparatus 100 for bending a small-sized target substrate and the bending apparatus 100 for bending a large-sized target substrate may have different sizes. Additionally, the main body 102 may include the adsorption parts 1300 having different shapes according to the target substrate. The adsorption part 1300 illustrated in FIG. 6 and FIG. 7 has a straight line shape extending in the first direction D1, but the adsorption part 1300 may have a curved shape according to other embodiments. In some embodiments, the length of the first direction D1 or the length of the second direction D2 of the adsorption part 1300 may be different. For example, various sizes and shapes of the bending apparatus 100 may be implemented for an appropriate bending process. As such, the shape and size of the bending apparatus 100 may vary, but by using the same connector 101, the bending apparatus 100 may be easily replaced or swapped. Replacing the multi-axis robot 200 to accommodate different display panels DP may be cumbersome. For example, the same connector 101 may mean that the connector 101 has the same shape and same function. Additionally, the same connector 101 may mean that the connector 101 that may transmit the same signal from the multi-axis robot 200 to the different bending apparatuses 100. The connector 101 has sufficient support strength to allow the bending apparatus 100 to be suspended from the multi-axis robot 200.

The connector 101 shown in FIG. 8 may be separated vertically. The upper part of the connector 101 may be coupled with the multi-axis robot 200, and the lower part of the connector 101 may be included in the bending apparatus 100. The upper and lower parts may be joined and connected to each other. This makes it easy to replace the bending apparatus 100 in the successive bending processes. The shape and size of the connector 101 are not limited. The connector 101 according to another embodiment may be an integral shape (or integral part) that is not separated into upper and lower parts. The connector 101 having the integral shape may be included in the bending apparatus 100 and may be combined with the multi-axis robot 200.

The connector 101 shown in FIG. 8 is disposed on the upper part of the main body 102. However, in another embodiment, the connector 101 may be disposed on the side of the main body 102. For example, the connector 101 and the main body 102 may be arranged along the first direction D1. Additionally, in another embodiment, the connector 101 may be disposed at the lower part of the main body 102. For example, in the manufacturing apparatus 10 of the display device, the connector 101 may be disposed on the multi-axis robot 200, and the main body 102 may be disposed on the connector 101.

The connector 101 that connects the multi-axis robot 200 and the main body 102 shown in FIG. 8 may rotate in place around the rotation axis parallel to the third direction D3. The bending apparatus 100 may also be rotated in place by rotating the connector 101 in place. For example, because the bending apparatus 100 may rotate 180 degrees with the third direction D3 as a reference, the adsorption part 1300 approaching the flexible printed circuit board CB may be freely selected. Therefore, the bending apparatus 100 according to embodiments of the present disclosure may not only move freely in space but may also freely change its posture (or orientation) in space.

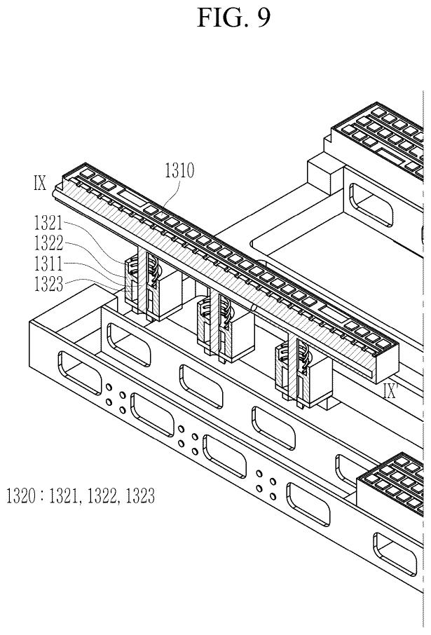

FIG. 9 is a view of a pressurizing part included in a bending apparatus according to an embodiment.

FIG. 9 illustrates a cross-sectional perspective view of the adsorption part 1300 taken along the line IX-IX′ in FIG. 6 showing the shape of the adsorption surface 1310 of the adsorption part 1300 that is pressurized up by the pressurizing part 1320.

The adsorption part 1300 may include the adsorption surface 1310, a supporting part 1311, and the pressurizing part 1320. The pressurizing part 1320 may include an elastic member 1321, a pressurization member 1322, and a bearing 1323.

The adsorption surface 1310 may be exposed along the third direction D3, which crosses (or intersects) each of the first direction D1 and the second direction D2. The target substrate may be placed on the adsorption surface 1310. The target substrate may be adsorbed or desorbed (e.g., adhered or removed) from the adsorption surface 1310. The pressurizing part 1320 configured to move the adsorption surface 1310 may be disposed between the adsorption surface 1310 and the extension frame 1200. The pressurizing part 1320 pressurizes the adsorption surface 1310 along the third direction D3 to enable the target substrate to be strongly adhered to the display panel DP.

The elastic member 1321 may temporarily deform in response to an external load or a deformation force and then return to its original shape when the force is removed. For example, the elastic member 1321 may be a spring.

The pressurization member 1322 may be supplied with power to perform the function of pressurizing up the adsorption surface 1310. The pressurization member 1322 may be disposed along the third direction D3 from the adsorption surface 1310. The pressurization member 1322 may pressurize the adsorption surface 1310 along the third direction D3. The pressurization member 1322 may receive power from the multi-axis robot via power lines. In another embodiment, the pressurization member 1322 may be powered from a battery included in the bending apparatus 100.

The bearing 1323 may reduce friction between shafts during the rotational or linear motion. For example, the bearing 1323 may be a ball bushing.

The elastic member 1321 may be disposed between the adsorption surface 1310 and the pressurization member 1322. The elastic member 1321 may cushion the impact when the pressurization member 1322 lifts the adsorption surface 1310. If an excessively strong force is transmitted from the pressurization member 1322 to the target substrate through the adsorption surface 1310 in a short period of time, the target substrate may be damaged. Accordingly, the elastic member 1321 prevents damage to the target substrate.

The bearing 1323 may be disposed inside the pressurization member 1322. As the pressurization member 1322 moves along the third direction D3, friction may occur with the supporting part 1311 that supports the adsorption surface 1310. The bearing 1323 may be disposed between the pressurization member 1322 and the supporting part 1311 to reduce friction.

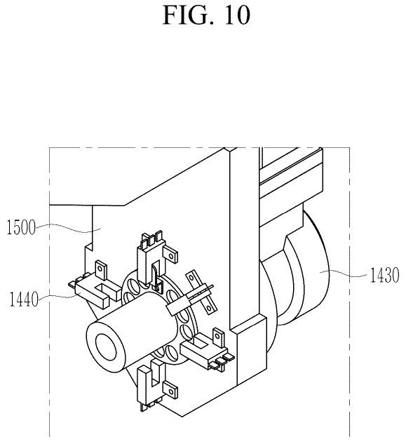

FIG. 10 is a view showing a sensor part included in a bending apparatus according to an embodiment.

The sensor part 1440 may be disposed between the rotation coupling part 1410 and the rotation reducer 1430. The sensor part 1440 may measure the rotation speed and rotation angle of the rotation coupling part 1410. The sensor part 1440 may measure the rotation speed and rotation angle of the central frame 1100 or the adsorption part 1300 by detecting the rotation speed and rotation angle of the rotation coupling part 1410. Additionally, the sensor part 1440 may measure the rotation speed and rotation angle of the pressurization frame 1800. The pressurization frame 1800 may include a position detection sensor specimen 1802 at an end of the first direction D1, which is closer to the rotation member 1400. The sensor part 1440 may measure the rotation speed by measuring the change in the rotation angle over time of the rotation coupling part 1410 or the pressurization frame 1800. The method by which the sensor part 1440 measures the rotation speed and rotation angle of the rotation coupling part 1410 or the pressurization frame 1800 is not limited. For example, the sensor part 1440 may be an optical rotational encoder. The optical rotational encoder may measure the rotation angle by using a disk with a photosensor and a light source attached.

FIG. 10 illustrates the sensor part 1440 disposed between the rotation coupling part and the rotation reducer in contact with the body frame 1500. The rotation axis that transfers the rotational kinetic energy from the rotation reducer 1430 to the rotation coupling part 1410 is shown cut away.

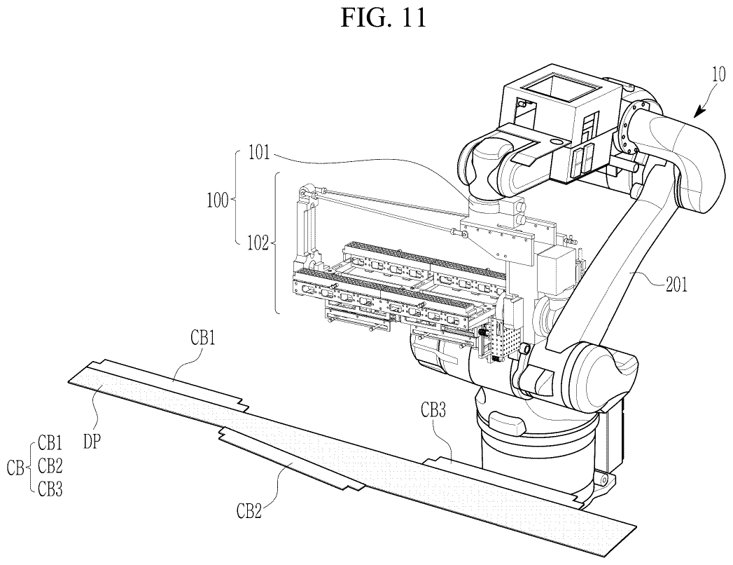

FIG. 11 to FIG. 14 are views illustrating a manufacturing method of a display device according to an embodiment.

FIG. 11 to FIG. 14 sequentially illustrate a process of bending and then pressurizing a flexible printed circuit board CB bonded to a display panel DP by using a bending apparatus 100 according to an embodiment. The display panel DP illustrated in FIG. 11 to FIG. 14 has a polygonal shape, and a first flexible printed circuit board CB1, a second flexible printed circuit board CB2, and a third flexible printed circuit board CB3 are each attached to different positions of the display panel DP. To perform a bending process on the display panel DP and the flexible printed circuit boards CB shown in FIG. 11 to FIG. 14 by using an affixed bending apparatus according to a comparative example, a plurality of bending apparatuses with different sizes and positions may be required. This may result in work inefficiency and waste of space. According to an embodiment, the bending apparatus 100 may perform the bending process by affixing the display panel DP and freely moving the bending apparatus 100. Because the bending apparatus 100 may move to the position where the flexible printed circuit board CB is disposed, the bending process may not be limited by the size and shape of the display panel DP. Additionally, after bending one of the plurality of flexible printed circuit boards CB, the preparation process for bending another flexible printed circuit board CB may be simplified.

FIG. 11 shows the bending apparatus 100 connected to the multi-joint robot 201. The manufacturing apparatus 10 of the display device according to an embodiment including the multi-joint robot 201 and the bending apparatus 100 may detect the position of the flexible printed circuit board CB to be bent. If necessary, a peeling process for peeling off the release paper RL of the adhesive member AM may be performed using the grip part (e.g., 1600 in FIG. 6) of the bending apparatus 100 before the bending process.

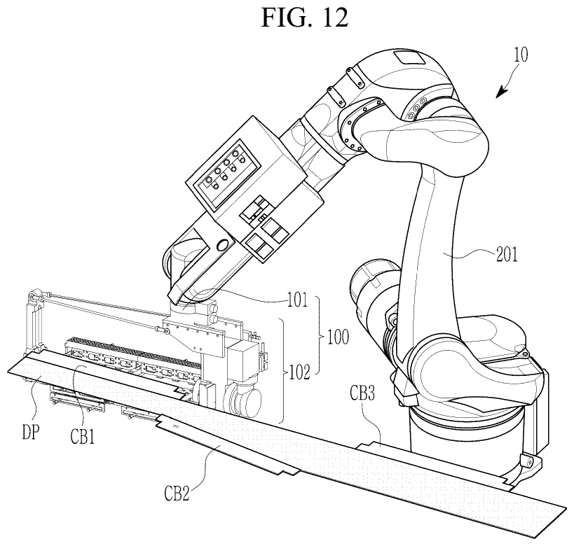

FIG. 12 shows the bending apparatus 100 moved closer to the first flexible printed circuit board CB1, which is the bending target. The bending apparatus 100 may move according to the motion of the multi-joint robot 201. The first flexible printed circuit board CB1 may be placed on the adsorption part (e.g., 1300 in FIG. 6) of the bending apparatus 100. The adsorption part 1300 of the bending apparatus 100 may adsorb the first flexible printed circuit board CB1. The first flexible printed circuit board CB1 adsorbed by the adsorption part 1300 may be bent in response to the movement of the bending apparatus 100.

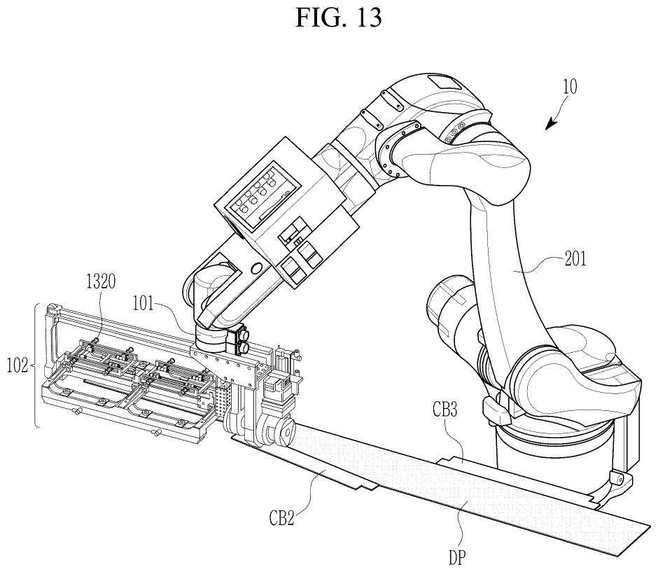

FIG. 13 is an illustration showing the first flexible printed circuit board CB1 after bending. The multi-joint robot 201 may move according to the bending orbit of the first flexible printed circuit board (e.g., CB1 in FIG. 12). Additionally, the adsorption part (e.g., 1300 in FIG. 6) may rotate 180 degrees around the first rotation axis (e.g., 1103 in FIG. 6) according to the bending orbit (or rotational path) of the first flexible printed circuit board CB1. The bending apparatus 100 may pressurize the first flexible printed circuit board CB1 to strongly adhere the bent first flexible printed circuit board CB1 to the display panel DP. For example, the bending apparatus 100 may pressurize the first flexible printed circuit board CB1 by using the motion of the multi-joint robot 201. In another embodiment, the bending apparatus 100 may pressurize the first flexible printed circuit board CB1 by using the pressurizing part 1320.

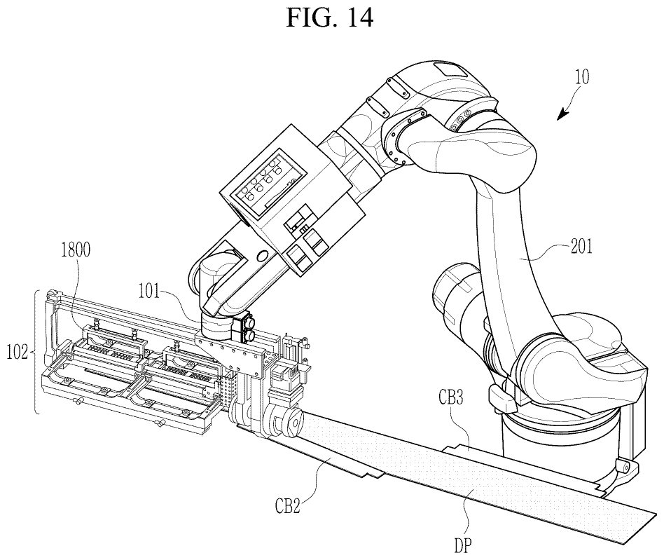

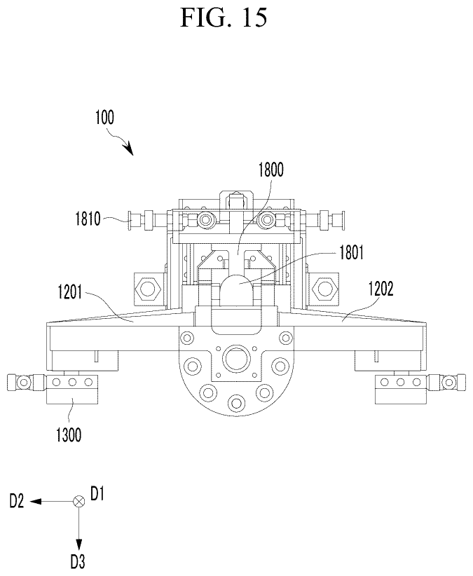

FIG. 14 illustrates a pressurization process of pressurizing the first flexible printed circuit board CB1 by the protruding part (e.g., 1810 in FIG. 13) by rotating the pressurization frame 1800. The pressurization frame 1800 and the protruding part 1810 may rotate about the second rotation axis (e.g., 1801 in FIG. 7). The pressurization process for pressurizing the first flexible printed circuit board CB1 by using the pressurization frame 1800 and the protruding part 1810 is described with reference to FIG. 15 to FIG. 17.

FIG. 15 to FIG. 17 are views showing a pressurization process of a bending apparatus according to an embodiment.

FIG. 15 to FIG. 17 illustrate the bending apparatus 100 that performs the pressurization process after performing the bending process on the target substrate. In the pressurization process, the adsorption part 1300 may be rotated 180 degrees compared to before the bending process. Additionally, in the pressurization process, the adsorption part 1300 may be in a state of adsorbing the target substrate. In the pressurization process, the pressurization frame 1800 of the bending apparatus 100 may rotate around the second rotation axis 1801. As the pressurization frame 1800 rotates, the protruding part 1810 extending from the pressurization frame 1800 in the second direction D2 may also rotate.

The protruding part 1810 may pressurize a part of the target substrate that the adsorption part 1300 is adsorbing and the other part. For example, the protruding part 1810 may pressurize an end side of the target substrate. A method of pressurizing the target substrate by using the motion of the multi-axis robot or a method of pressurizing the target substrate by using the pressurizing part 1320 may pressurize only a part of the target substrate that overlaps the adsorption surface 1310. However, the method of pressurizing the target substrate by utilizing the rotational motion of the protruding part 1810 may also pressurize a part of the target substrate that does not overlap the adsorption surface 1310.

FIG. 15 shows the bending apparatus 100 immediately after the bending process is completed. The pressurization frame 1800 and the protruding part 1810 may maintain a neutral state without rotation.

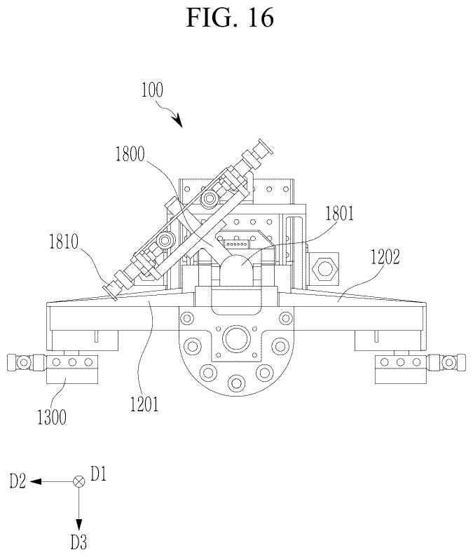

FIG. 16 illustrates the bending apparatus 100 before the protruding part 1810 is in contact with the target substrate after the pressurization process has begun. The pressurization frame 1800 and the protruding part 1810 may be tilted about 45 degrees compared to the neutral state.

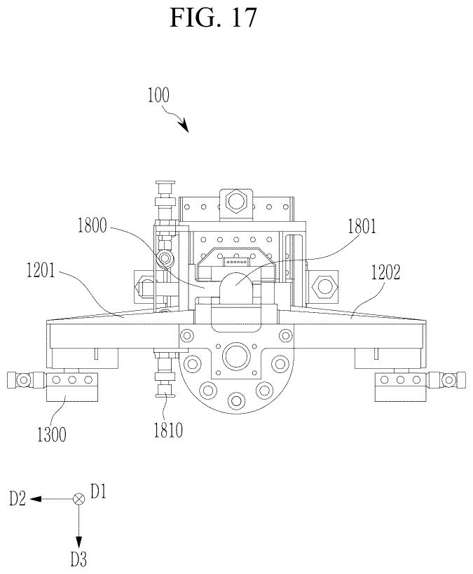

FIG. 17 illustrates the bending apparatus 100 with the protruding part 1810 in contact with the target substrate during the pressurization process. The target substrate may be pressurized by the protruding part 1810. The protruding part 1810 may pressurize a part of the target substrate that does not overlap the adsorption surface 1310. After the pressurization by the protruding part 1810 is completed, the pressurization frame 1800 and the protruding part 1810 may be rotated in opposite directions to return to a neutral state.

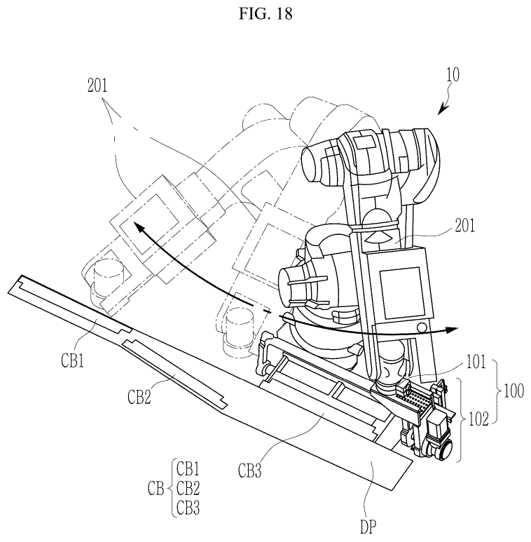

FIG. 18 illustrates the bending apparatus according to an embodiment for sequentially bending the different flexible printed circuit boards.

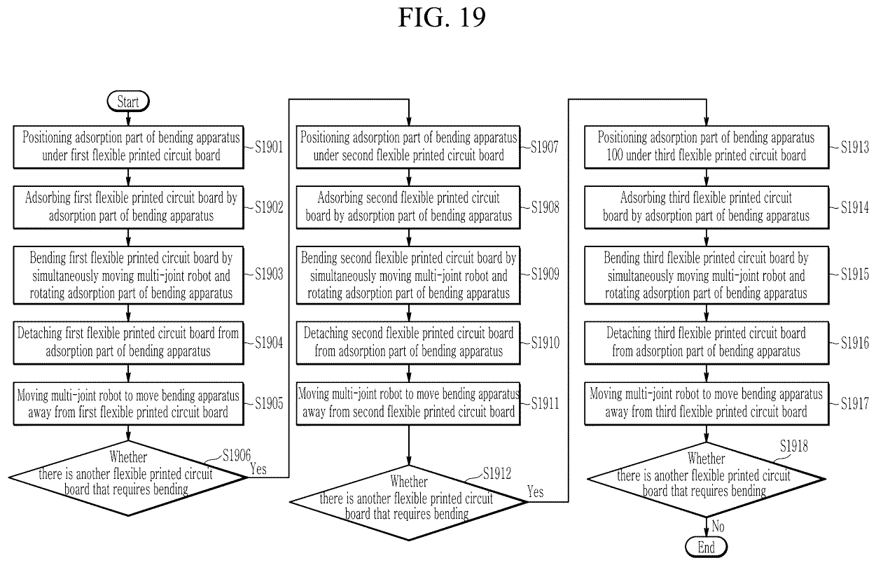

FIG. 18 illustrates the bending apparatus 100 for bending the third flexible printed circuit board CB3 after bending the first flexible printed circuit board CB1 and the second flexible printed circuit board CB2. The adsorption part (e.g., 1300 in FIG. 6) for bending the first flexible printed circuit board CB1 and the third flexible printed circuit board CB3 may be the first adsorption part (e.g., 1301 in FIG. 6). The adsorption part 1300 for bending the second flexible printed circuit board CB2 may be a second adsorption part (e.g., 1302 in FIG. 6) disposed on a side opposite to the first adsorption part 1301. The protruding part 1810, which pressurizes the first flexible printed circuit board CB1 and the third flexible printed circuit board CB3 by the pressurization process, may be disposed on the first adsorption part 1301 side. The protruding part 1810, which pressurizes the second flexible printed circuit board CB2 by the pressurization process, may be disposed on the second adsorption part 1302 side because the second flexible printed circuit board CB2 is bonded to the side opposite to the side of the display panel DP to which the first flexible printed circuit board CB1 and the third flexible printed circuit board CB2 are bonded. To perform the bending process and the pressurization process for the second flexible printed circuit board CB2, it may be easier to use the adsorption part 1300 and the protruding part 1810 of the opposite side to the adsorption part 1300 and the protruding part 1810 used in the first flexible printed circuit board CB1 and the third flexible printed circuit board CB3. To use the adsorption part 1300 used in the first flexible printed circuit board CB1 in the second flexible printed circuit board CB2, there may be the inconvenience of having to rotate the bending apparatus 100 by 180 degrees. The process of bending the plurality of flexible printed circuit boards CB attached to one display panel DP through the manufacturing apparatus 10 of the display device is described with reference to a flowchart of FIG. 19.

FIG. 19 is a flowchart describing a manufacturing method of a display device according to an embodiment.

First, a step (S1901) of positioning the adsorption part 1300 of the bending apparatus 100 under the first flexible printed circuit board CB1 may be performed. The bending apparatus 100 may be moved according to the motion of the multi-joint robot 201. Afterwards, a step (S1902) of adsorbing the first flexible printed circuit board CB1 by the adsorption part 1300 of the bending apparatus 100 may be performed. By the adsorption part 1300 adsorbing the first flexible printed circuit board CB1, the first flexible printed circuit board CB1 may be affixed to the bending apparatus 100. Afterwards, a step (S1903) of bending the first flexible printed circuit board CB1 by concurrently (or simultaneously) moving the multi-joint robot 201 and rotating the adsorption part 1300 of the bending apparatus 100 may be performed. The first flexible printed circuit board CB1 may be bent along a bending orbit (or rotational path). Afterwards, a step (S1904) of detaching the first flexible printed circuit board CB1 from the bending apparatus 100 may be performed. Because the bending process for the first flexible printed circuit board CB1 has been completed, the bending apparatus 100 may be prepared for separation from the first flexible printed circuit board CB1. Afterwards, a step (S1905) of moving the multi-joint robot 201 to move the bending apparatus 100 away from the first flexible printed circuit board CB1 may be performed. A step (S1906) of determining whether or not there is another flexible printed circuit board to be bent may be performed at the same time as step (S1905) or subsequently.

Because the display panel shown in FIG. 18 includes the second flexible printed circuit board CB2, a step (S1907) of positioning the adsorption part 1300 of the bending apparatus 100 under the second flexible printed circuit board CB2 may be performed. Afterwards, a step (S1908) of adsorbing the second flexible printed circuit board CB2 by the adsorption part 1300 of the bending apparatus 100 may be performed. Afterwards, a step (S1909) of bending the second flexible printed circuit board CB2 by concurrently (or simultaneously) moving the multi-joint robot 201 and rotating the adsorption part 1300 of the bending apparatus 100 may be performed. The second flexible printed circuit board CB2 may be bent according to a bending orbit (or rotational path). Next, a step (S1910) of detaching the second flexible printed circuit board CB2 from the bending apparatus 100 may be performed. Because the bending process for the second flexible printed circuit board CB2 is completed, the bending apparatus 100 may be prepared for separation from the second flexible printed circuit board CB2. Next, a step (S1911) of moving the multi-joint robot 201 to move the bending apparatus 100 away from the second flexible printed circuit board CB2 may be performed. At the same time as step (S1911) or after, a step (S1912) may be performed to determine whether or not another flexible printed circuit board is to be bent.

Because the display panel shown in FIG. 18 includes a third flexible printed circuit board CB3, a step (S1913) of positioning the adsorption part 1300 of the bending apparatus 100 under the third flexible printed circuit board CB3 may be performed. Next, a step (S1914) of adsorbing the third flexible printed circuit board CB3 by the adsorption part 1300 of the bending apparatus 100 may be performed. Next, a step (S1915) of bending the third flexible printed circuit board CB3 by concurrently (or simultaneously) moving the multi-joint robot 201 and rotating the adsorption part 1300 of the bending apparatus 100 may be performed. The third flexible printed circuit board CB3 may be bent along a bending orbit (or rotational path). Next, a step (S1916) of detaching the third flexible printed circuit board CB3 from the bending apparatus 100 may be performed. Because the bending process for the third flexible printed circuit board CB3 is completed, the bending apparatus 100 may be prepared to separate from the third flexible printed circuit board CB3. Afterwards, a step (S1917) of moving the multi-joint robot 201 to move the bending apparatus 100 away from the third flexible printed circuit board CB3 may be performed. At the same time as or after step (S1917), a step (S1918) may be performed to determine whether or not another flexible printed circuit board is to be bent. When all the flexible printed circuit boards CB bonded to the display panel DP have been bent, the bending apparatus 100 may end the bending process.

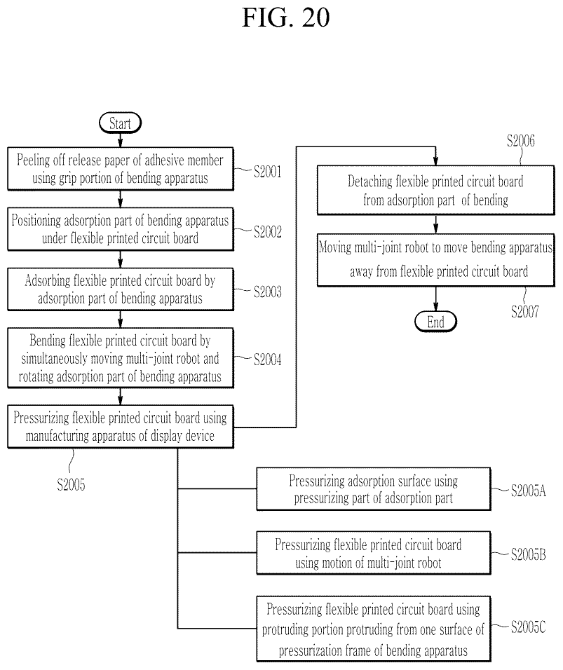

FIG. 20 is a flowchart describing a manufacturing method of a display device according to an embodiment.

FIG. 20 is a flowchart describing steps of a peeling process and a pressurization process that may be performed before and after a bending process using a bending apparatus 100 according to an embodiment.

First, a step (S2001) of peeling off the release paper RL of the adhesive member AM by using the grip part 1600 of the bending apparatus 100 may be performed. The step (S2001) may be a peeling process. The peeling process may including moving the grip part 1600 of the bending apparatus 100 closer to the release paper RL by using the motion of the multi-joint robot 201. Next, the grip part 1600 may peel off the release paper RL. Afterwards, a step (S2002) of positioning the adsorption part 1300 of the bending apparatus 100 under the flexible printed circuit board CB may be performed. Afterwards, a step (S2003) of adsorbing the flexible printed circuit board CB by the adsorption part 1300 of the bending apparatus 100 may be performed. Afterwards, a step (S2004) of bending the flexible printed circuit board CB by concurrently (or simultaneously) moving the multi-joint robot 201 and rotating the adsorption part 1300 of the bending apparatus 100 may be performed. Afterwards, a step (S2005) of pressurizing the flexible printed circuit board CB by using the manufacturing apparatus 10 of the display device may be performed.

The method for pressurizing the flexible printed circuit board CB, which may include step (S2005), is described. First, step (S2005) may include a step (S2005A) of pressurizing the adsorption surface 1310 using the pressurizing part 1320 of the adsorption part 1300. Secondly, step (S2005) may include a step (S2005B) of pressurizing the flexible printed circuit board CB by using the motion of the multi-joint robot 201. Third, step (S2005) may include a step (S2005C) of pressurizing the flexible printed circuit board CB by using a protruding part 1810 protruding from a surface of the pressurization frame 1800 of the bending apparatus 100. Step (S2005) may include at least one of steps (S2005A, S2005B, and S2005C). Steps (S2005A, S2005B and S2005C) may be performed concurrently (or simultaneously) or sequentially. After step (S2005) is performed, step (S2006) of detaching the flexible printed circuit board CB from the adsorption part 1300 of the bending apparatus 100 may be performed. Afterwards, the step (S2007) of moving the multi-joint robot 201 to move the bending apparatus 100 away from the flexible printed circuit board CB may be performed.

The size and shape of the display panel DP may vary depending on different applications and user needs. For example, the display panel DP may be a square shape. In another embodiment, the display panel DP may have a free curved line shape on one side. As the shape and size of the display panel DP become more diverse, the position at which the flexible printed circuit board CB is bonded to the display panel DP may also become more diverse. Additionally, there may be cases in which the plurality of flexible printed circuit boards CB are bonded to one display panel DP. Although it is a single display panel DP, the bonding environment in which the flexible printed circuit board CB is bonded may differ depending on the position of the display panel DP. For example, the bonding environment may be the shape of the display panel DP to which the flexible printed circuit board CB is bonded. Additionally, the bonding environment may be the size of the display panel DP to which the flexible printed circuit board CB is bonded. Additionally, the bonding environment may be the width or length of the flexible printed circuit board CB.

Embodiments of the present disclosure may provide the manufacturing apparatus 10 of the display device, the bending apparatus 100, and the manufacturing method of the display device for bending a target substrate regardless of the shape and size of a display panel DP. In addition, embodiments of the present disclosure can provide the manufacturing apparatus 10 of the display device, the bending apparatus 100, and the manufacturing method of the display device for bending the target substrate regardless of the position of the display panel DP to which the flexible printed circuit board CB is attached. In addition, embodiments of the present disclosure may provide the manufacturing apparatus 10 of the display device, the bending apparatus 100, and the manufacturing method of the display device for bending the target substrate without requiring additional equipment even when the plurality of flexible printed circuit boards CB are to be attached to one display panel DP.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims and their equivalents.

What is claimed is:

1. A manufacturing apparatus of a display device comprising:
a multi-axis robot, and
a bending apparatus comprising:
a connector configured to be removably mounted to the multi-axis robot; and
a main body supported by the connector and configured to bend a target substrate, the main body comprising:
a central frame extending in a first direction;
an extension frame integrally combined with the central frame and extending from the central frame in a second direction crossing the first direction;
an adsorption part on the extension frame; and
a rotation member connected to an end of the central frame and configured to rotate the adsorption part about a first rotation axis that is parallel to the first direction.

2. The manufacturing apparatus of the display device of claim 1, wherein:
the extension frame comprises a first extension frame and a second extension frame extending in opposite directions from the central frame along the second direction, and
the adsorption part comprises a first adsorption part on the first extension frame and a second adsorption part on the second extension frame.

3. The manufacturing apparatus of the display device of claim 1, wherein the adsorption part comprises:
an adsorption surface configured to receive the target substrate; and
a pressurizing part between the adsorption surface and the extension frame and configured to move the adsorption surface.

4. The manufacturing apparatus of the display device of claim 1, wherein the rotation member comprises:
a rotation coupling part connected to an end of the central frame and configured to rotate around the first rotation axis;
a rotation reducer connected to the rotation coupling part in the first direction; and
a rotation driving part connected to the rotation reducer and configured to provide a driving torque that rotates the rotation coupling part.

5. The manufacturing apparatus of the display device of claim 4, wherein the rotation member comprises a sensor part between the rotation coupling part and the rotation reducer configured to detect a rotation angle of the central frame.

6. The manufacturing apparatus of the display device of claim 1, wherein the central frame has a first end to which the rotation member is coupled and a second end opposite to the first end in the first direction, and
wherein the main body comprises:
a body frame between the connector and the rotation member;
a first reinforcement frame extending from the second end along a third direction crossing each of the first direction and the second direction; and
a second reinforcement frame separated from the central frame and connecting the first reinforcement frame and the body frame.

7. The manufacturing apparatus of the display device of claim 6, wherein a minimum separation distance between the central frame and the second reinforcement frame is greater than a length of the extension frame in the second direction.

8. The manufacturing apparatus of the display device of claim 1, wherein the main body comprises:
a body frame between the connector and the rotation member; and
a grip part extending along the second direction from the body frame and having a shutoff-capable forceps shape at an end of the second direction.

9. The manufacturing apparatus of the display device of claim 1, wherein the main body comprises:
a pressurization frame extending from the central frame along a third direction crossing each of the first direction and the second direction configured to rotate about a second rotation axis parallel to the first direction; and
a protruding part that protrudes in the second direction from a surface of the pressurization frame extending along the first direction.

10. A bending apparatus comprising:
a connector configured to be removably attachable to a multi-axis robot; and
a main body configured to be suspended and supported by the connector and configured to bend a target substrate, the main body comprises:
a central frame extending in a first direction,
an extension frame integrally combined with the central frame and extending from the central frame in a second direction crossing the first direction,
an adsorption part on the extension frame, and
a rotation member connected to an end of the central frame and configured to rotate the adsorption part about a first rotation axis that is parallel to the first direction.

11. The bending apparatus of claim 10, wherein:
the extension frame comprises a first extension frame and a second extension frame extending in opposite directions from the central frame along the second direction, and
the adsorption part comprises a first adsorption part on the first extension frame and a second adsorption part on the second extension frame.

12. The bending apparatus of claim 10, wherein the adsorption part comprises:
an adsorption surface configured to place the target substrate; and
a pressurizing part between the adsorption surface and the extension frame and configured to move the adsorption surface.

13. The bending apparatus of claim 10, wherein the rotation member comprises:
a rotation coupling part connected to an end of the central frame and configured to rotate about the first rotation axis;
a rotation reducer connected to the rotation coupling part in the first direction; and
a rotation driving part connected to the rotation reducer and configured to provide a driving torque to rotate the rotation coupling part.

14. The bending apparatus of claim 10, wherein the central frame has a first end to which the rotation member is coupled and a second end opposite to the first end in the first direction, and
wherein the main body comprises:
a body frame between the connector and the rotation member;
a first reinforcement frame extending from the second end along a third direction crossing each of the first direction and the second direction; and
a second reinforcement frame separated from the central frame and connecting the first reinforcement frame and the body frame.

15. The bending apparatus of claim 10, wherein the main body comprises:
a body frame between the connector and the rotation member; and
a grip part extending along the second direction from the body frame and having a shutoff-capable forceps shape at an end of the second direction.

16. The bending apparatus of claim 10, wherein the main body comprises:
a pressurization frame extending from the central frame along a third direction crossing each of the first direction and the second direction and configured to rotate about a second rotation axis parallel to the first direction; and
a protruding part that protrudes in the second direction from a surface of the pressurization frame extending along the first direction.

17. A manufacturing method of a display device, the method comprising:
preparing a bending apparatus comprising a connector configured to be removably attachable from a multi-axis robot and a main body comprising an adsorption part and suspended from the connector;
moving the multi-axis robot to position the adsorption part under a target substrate;
adsorbing a part of the target substrate by the adsorption part;
bending the target substrate by moving the multi-axis robot and concurrently rotating the adsorption part; and
moving the multi-axis robot to move the adsorption part away from the target substrate.

18. The manufacturing method of the display device of claim 17, wherein:
the adsorption part comprises an adsorption surface and a pressurizing part connected to the adsorption surface, and
the method further comprises pressurizing the adsorption surface by using the pressurizing part.

19. The manufacturing method of the display device of claim 17, wherein:
the main body comprises a grip part having a shutoff-capable forceps shape at an end, and
the method further comprises peeling off a release paper by using the grip part.

20. The manufacturing method of the display device of claim 17, wherein:
the main body comprises:
a central frame extending in a first direction;
an extension frame integrally combined with the central frame and extending from the central frame in a second direction crossing the first direction;
a pressurization frame configured to extend from the central frame along a third direction crossing each of the first direction and the second direction and to rotate about a second rotation axis parallel to the first direction; and
a protruding part protruding in the second direction on a surface of the pressurization frame extending along the first direction, and
the method further comprises pressurizing the protruding part of the bent target substrate by rotating the pressurization frame.
